(19) United States
(12) Patent Application Publication
(10) Pub. No.: US 2012/0045570 A1
(43) Pub. Date: Feb. 23, 2012

(54) Plating solution for forming tin alloy and method of forming tin alloy film using the same

(75) Inventors: Yong Seok Kim, Seongnam (KR); Jin Hyuck Yang, Yongin (KR); Soo Young Ji, Suwon (KR)

(73) Assignee: SAMSUNG ELECTRO-MECHANICS CO., LTD., Suwon (KR)

(21) Appl. No.: 12/929,040

(22) Filed: Dec. 23, 2010

(30) Foreign Application Priority Data
Aug. 18, 2010 (KR) 10-2010-0079983

(51) Int. Cl. H05K 3/10; C23C 18/48

(52) U.S. Cl. 427/97.3; 106/1.22; 427/443.1

(57) ABSTRACT

There are provided a plating solution for forming a tin alloy, and a method of forming a tin alloy film by using the same. The plating solution for forming a tin alloy, the plating solution includes a tin salt and one or more metal salts each comprising indium or zinc, and at least one reducing agent selected from the group consisting of boron hydride compounds, the reducing agent providing electrons to metal ions of the metal salts and tin ions of the tin salt to form a tin alloy film on an object to be plate.

### CROSS-REFERENCE TO RELATED APPLICATIONS

This application claims the priority of Korean Patent Application No. 10-2010-0079983 filed on Aug. 18, 2010, in the Korean Intellectual Property Office, the disclosure of which is incorporated herein by reference.

### BACKGROUND OF THE INVENTION

1. Field of the Invention

The present invention relates to a plating solution for forming a tin alloy and a method of forming a tin alloy film using the same, and more particularly, to a plating solution for forming a tin alloy, capable of allowing for the formation of a dense tin alloy film having a uniform thickness, and a method of forming a tin alloy film using the same.

2. Description of the Related Art

Precise placing is replacing solder balls that have previously been used to mount IC chips or the like on a wiring board, in an effort to reduce costs and to meet demands for higher-density interconnection patterns and slimmer boards.

A tin film is formed on a wiring board through electro-plating. However, the electro-plating may bring about an uneven current density distribution, which may cause the tin film to have uneven thickness. Consequently, difficulties occur in matching between an IC chip and interconnections on a board, and the overall reliability of a product can be deteriorated. Furthermore, apparatuses for voltage application are put into a plating tank at the time of the electro-plating. Thus, the use of large and expensive apparatuses may complicate processes and increase costs.

Therefore, a method of forming a tin film through electroless plating has been adopted. The electroless plating provides high plating performance and thus causes a tin film to be dense and uniform in thickness, thereby enhancing the overall quality of a product.

An example of an electroless plating method includes an electroless immersion plating method employing the following principle: metal atoms of a wiring board to be plated are eluted into a plating solution as metal ions, and tin ions that have received electrons from the metal atoms in the plating solution are deposited on the surface of the wiring board (plating).

The electroless immersion plating method may allow for the formation of a tin film having a predetermined thickness or greater; however, it may create gaps between a wiring board and a tin film. Since metal atoms of a wiring board are eluted into a plating solution, the phenomenon of the erosion of the wiring board, intermetallic diffusion, under-cut or the like may interfere with the manufacturing of highly reliable wiring boards.

In order to address the aforementioned limitation, there has been an attempt to perform tin plating by using an electroless reduction plating method, rather than the electroless immersion plating. However, a reducing agent allowing for tinplating to a desired extent despite tin's low autocatalytic activity has not been developed yet. Therefore, developing a proper reducing agent is becoming an important issue.

### SUMMARY OF THE INVENTION

An aspect of the present invention provides a plating solution for forming a tin alloy, capable of allowing for the formation of a dense tin alloy film having a uniform thickness, and a method of forming a tin alloy film using the same.

According to an aspect of the present invention, there is provided a plating solution for forming a tin alloy, the plating solution including: a tin salt and one or more metal salts each including indium or zinc; and at least one reducing agent selected from the group consisting of boron hydride compounds, the reducing agent providing electrons to metal ions of the metal salts and tin ions of the tin salt to thereby form a tin alloy film on an object to be plated.

The tin salt may include a ligand having two or more carboxyl groups.

The tin salt may include an oxalate expressed by a chemical formula below:

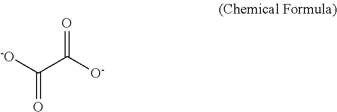

A content of the tin salt may range from 5 g/L to 20 g/L.

A content of the one or more metal salts including the indium or the zinc may range from 1 g/L to 10 g/L.

The boron hydride compounds may be sodium boron hydride, potassium boron hydride, or lithium boron hydride.

A content of the reducing agent may range from 1 g/L to 10 g/L.

The plating solution for forming a tin alloy may have a pH of between 10 and 11.

The plating solution may further include at least one additive selected from the group consisting of a complexing agent, an accelerator and an oxidation inhibitor.

The plating solution may further include: at least one first complexing agent selected from the group consisting of a carbonyl compound or an amino compound having a shared electron pair to allow for a coordinate bond with the metal ions and the tin ions; and at least one second complexing agent selected from the group consisting of a carbonyl compound and an amino compound having lower bonding energy with respect to the tin ions than that of the first complexing agent.

A content of the first complexing agent may range from 50 g/L to 150 g/L, and a content of the second complexing agent may range from 1 g/L to 20 g/L.

According to another aspect of the present invention, there is provided a method of forming a tin alloy film, the method including: preparing a plating solution for forming a tin alloy, the plating solution including: a tin salt and one or more metal salts each including indium or zinc; and at least one reducing agent selected from the group consisting of boron hydride compounds, the reducing agent providing electrons to metal ions of the metal salts and tin ions of the tin salt for the formation of a tin alloy film on an object to be plated; and immersing the object into the plating solution to thereby form a tin alloy film.

The tin salt may be tin oxalate including an oxalate expressed by a chemical formula below:

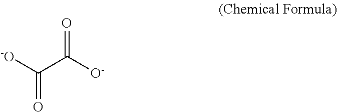

The plating solution may have a pH of between 10 and 11.

The object to be plated may be a printed circuit board, and the tin alloy film may be formed on a circuit pattern of the printed circuit board to thereby form a pad for bonding with a stub bump.

The method may further include forming a nickel layer on the circuit pattern before the forming of the tin alloy film.

### BRIEF DESCRIPTION OF THE DRAWINGS

The above and other aspects, features and other advantages of the present invention will be more clearly understood from the following detailed description taken in conjunction with the accompanying drawings, in which:

FIGS. 1 through 3 are schematic cross-sectional views illustrating the individual processes associated with a method of forming a tin alloy film on a printed circuit board according to an exemplary embodiment of the present invention.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art.

According to an exemplary embodiment of the present invention, a plating solution for forming a tin alloy may include: a tin salt and one or more metal salts each including indium or zinc; and at least one reducing agent selected from the group consisting of boron hydride compounds, the reducing agent providing electrons to metal ions of the metal salt and tin ions of the tin salt to thereby form a tin alloy film on an object to be plated (hereinafter, also referred to as a plating object).

According to an exemplary embodiment of the present invention, a plating solution for forming a tin alloy contains a reducing agent therein. Electrons required for the precipitation of a tin alloy are supplied by the oxidation of the reducing agent. That is, electrons generated by the reducing agent are transferred to indium and/or zinc ions and tin ions, and the reduced indium and/or zinc ions and tin ions are deposited on a plating object) to thereby form a tin alloy film. In this case, the tin alloy film can be formed without causing any damage to the plating object, such as corrosion, because no metal in the plating object is dissolved to provide electrons, unlike in the related art electroless immersion reaction method. Accordingly, an electronic-component mounting board can be manufactured without damaging thin-film type metal interconnections for example.

The plating solution for forming a tin alloy, according to an exemplary embodiment of the present invention, is used to finally form a tin alloy film containing the tin salt and the metal salt including at least one of indium and zinc.

According to this exemplary embodiment, the tin salt may utilize a combination of tin ions and a ligand (complex agents) having two or more carboxyl groups. The ligand having carboxyl groups forms a coordinate bond with the tin ions in the plating solution to thereby create a chelate compound, which may act as a complexing agent.

The ligand having two or more carboxyl groups, although not limited thereto, may utilize, for example, an oxalate expressed by a chemical formula below:

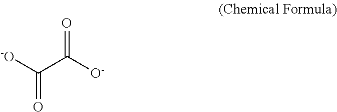

The oxalate is two carboxyl groups placed adjacent to each other, and has high bonding energy with respect to tin ions.

Typically, tin salts bound to halogen elements, such as Cl, F or the like, or sulfuric acid tin salts, have generally been used. However, halogen ions, sulfate ions or the like may cause the corrosion of a plating object, and thus fail to increase a plating rate.

In contrast, tin oxalate may serve to prevent the corrosion of a plating object and may adsorb onto the surface of the plating object to thereby suppress reactions, which may induce the corrosion thereof. According to an exemplary embodiment of the present invention, a tin alloy film is formed by using such tin oxalate. Thus, the corrosion of the plating object is prevented, and an increased plating rate can be ensured.

Furthermore, tin ions form sludge in the case in which the tin ions react to a reducing agent in a plating solution, rather than on a plating object. However, if a compound such as oxalate, which has high bonding energy with respect to tin ions, acts as a complexing agent as in this exemplary embodiment, the possibility of sludge generation can be reduced, thereby ensuring a sufficient level of stability of a plating solution and facilitating temperature control for increasing a plating rate.

Furthermore, by using the tin salt as described above, a small amount of reducing agent, i.e. the boron hydride compound, is required.

The content of the tin salt, although not limited thereto, may range from 5 g/L to 20 g/L. The tin salt of less than 5 g/L may slow down the plating rate, and the tin salt exceeding 20 g/L may destabilize the plating solution and form sludge or form a tin film on an undesired area.

According to the exemplary embodiment of the present invention, the plating solution for forming a tin alloy also includes one or more metal salts, each including indium or zinc for the formation of a tin alloy film.

The metal salts are not particularly limited and may utilize indium acetate, zinc acetate or the like.

The metal salts and the tin salt may be used to form a binary system (two-component system) tin alloy of In—Sn or Zn—Sn, or a ternary system (three-component system) tin alloy of In—Zn—Sn.

The binary-system tin alloy or the ternary-system tin alloy has a lower melting point than pure tin, thereby ensuring enhanced solderability. When the binary-system tin alloy or the ternary-system tin alloy contains In and/or Zn at a specific molar ratio, the binary- or ternary-system tin alloy has a lower melting point than pure tin. Therefore, the content of the metal salts may be adjusted so as to meet the specific molar ratio.

In more detail, a binary system tin alloy of In—Sn may be prepared to have an In molar fraction of between 0.1% and 99%. A binary tin alloy of Zn—Sn may be prepared to have a Zn molar fraction of between 0.1% and 20%.

The content of the metal salts including indium or zinc, although not limited thereto, may range from 1 g/L to 30 g/L according to a desired alloy ratio.

According to the exemplary embodiment of the present invention, the plating solution for forming a tin alloy may also include at least one reducing agent selected from the group consisting of boron hydride compounds.

The reducing agent, contained in the plating solution for electrolessly forming a tin alloy, needs to be able to generate electrons by being oxidized so that the indium and/or zinc ions and tin ions are reduced by the generated electrons.

The autocatalytic precipitation of tin is difficult due to tin's high hydrogen overvoltage and low autocatalytic activity. However, if a boron hydride compound is used as the reducing agent, electrons are transferred to the tin ions and the tin ions are reduced so that a tin alloy can be precipitated stably on a plating object.

The boron hydride compound is a strong reducing agent and enables the autocatalytic activity of tin.

The boron hydride compound, although not limited thereto, may utilize boron sodium boron hydride, potassium boron hydride, lithium boron hydride, or a mixture thereof, for example.

The content of the reducing agent, although not limited thereto, may range from 1 g/L to 10 g/L.

The reducing agent of less than 1 g/L makes it difficult to precipitate the tin ions, and requires a lengthy period of time in the precipitation thereof. An amount of reducing agent exceeding 10 g/L may destabilize the plating solution.

A pH of the plating solution for forming a tin alloy, according to the exemplary embodiment of the present invention, may range from 10 to 11. When the plating solution for electrolessly forming a tin alloy is acidic, electrons generated by the oxidation of the boron hydride compound react to hydrogen ions in the plating solution to thereby generate hydrogen gases, interfering with the electro-deposition of the tin ions and the indium and/or zinc ions. Therefore, in order to stably transfer electrons to the tin ions and the indium and/or zinc ions, the plating solution for electrolessly forming a tin alloy may have a pH of between 10 and 11.

According to the exemplary embodiment of the present invention, the plating solution for forming a tin alloy may additionally include other additives such as a complexing agent, an accelerator, an oxidation inhibitor and the like.

The complexing agent serves to prevent the metal ions from being reduced and precipitated within the plating solution during plating, and to suppress sludge generation caused when the metal ions react to the reducing agent within the plating solution.

According to the exemplary embodiment of the present invention, the plating solution for forming a tin alloy may include at least one first complexing agent selected from the group consisting of a carbonyl compound or an amino compound having a shared electron pair to allow for a coordinate bond with the metal ions and the tin ions. The first complexing agent has high bonding energy with respect to the tin ions so as to provide solution stability. The first complexing agentx may utilize, for example, an ethylene diamine tetraacetic acid (EDTA), a [bis(phosphonomethyl)amino] methyl phosphonic acid, a trans-1,2-diaminocyclohexane-N,N,N′,N′-tetraacetic acid, an ethylenediamine-N,N′-disuccinic acid, or Sodium citrate, but it is not particularly limited.

The content of the first complexing agent may range from 50 g/L to 150 g/L for example, but it is not particularly limited thereto. The first complexing agent in an amount of less than 50 g/L may react to the reducing agent and generate sludge in the plating solution, and the first complexing agent in an amount exceeding 150 g/L may lower the plating rate.

Furthermore, according to the exemplary embodiment of the present invention, the plating solution for forming a tin alloy may include at least one second complexing agent selected from the group consisting of a carbonyl compound and an amino compound having lower bonding energy with respect to the tin ions than that of the first complexing agent.

The second complexing agent may utilize, for example, oxalate having a structure in which two carboxyl groups are placed adjacent to each other, but it is not limited thereto. This second complexing agent may form a coordinate bond with the tin ions to thereby create a chelate compound and therefore lower the possibility that the tin ions react to the reducing agent within the plating solution, rather than on a plating object.

In the above manner, the possibility of sludge generation within the plating solution is reduced, thereby facilitating temperature control for increasing the plating rate.

The content of the second complexing agent may range from 1 g/L to 20 g/L for example, but it is not limited thereto. Even when the plating solution does not contain the second complexing agent, the plating rate can be increased since the tin salt includes the ligand having carboxyl groups. However, in the case in which the second complexing agent is used, the plating rate can be controlled according to a temperature which is to be used.

The second complexing agent exceeding 20 g/L may destabilize the plating solution.

The accelerator serves to prevent the reducing agent from naturally decomposing. The accelerator may be used to increase the plating rate.

The reducing agent needs to have high stability within the plating solution and to not easily decompose or react to another additive within the plating solution. Thereby, the use of the accelerator may ensure the stability of the reducing agent and improve the electron transfer to the tin ions.

The accelerator is not particularly limited, and may utilize a known substance, provided that it is capable of preventing the natural deposition of the boron hydride compound. For example, the accelerator may utilize sodium acetate.

The content of accelerator, although not limited thereto, may range from 1 mg/L to 20 g/L for example. The accelerator of less than 1 mg/L reduces the plating rate due to the natural deposition of the reducing agent, and the accelerator exceeding 20 g/L may destabilize the plating solution.

Furthermore, the oxidation inhibitor may increase the plating rate by preventing the divalent tin ions from being oxidized into tetravalent tin ions. The oxidation inhibitor is not particularly limited provided that it is in use in the related art. For example, the oxidation inhibitor may utilize a phosphorous, compound, a hydrazine derivative or the like, and an example thereof may include sodium hypophosphate.

The content of the oxidation inhibitor, although not limited thereto, may range from 1 mg/L to 20 g/L for example. The oxidation inhibitor in an amount of less than 1 mg/L may slow down the plating rate, and the oxidation inhibitor exceeding 20 g/L may be placed on the surface of a plating object, interfering with an oxidation reaction between the plating object and the boron hydride compound used as the reducing agent.

According to another exemplary embodiment of the present invention, there is provided a method of forming a tin alloy film by using the plating solution for forming a tin alloy.

The method of forming a tin alloy film, according to this exemplary embodiment of the present invention, is carried out by using the aforementioned plating solution for forming a tin alloy, and the components and operations thereof are the same as those described above.

According to this exemplary embodiment of the present invention, the plating solution for forming a tin alloy is prepared, and a plating object is then immersed into the plating solution for forming a tin alloy.

The immersion may be performed at a temperature of between 25° C. and 80° C. for 30 to 60 minutes.

The plating object, although not limited thereto, may be a product formed of copper or another metal. Furthermore, the plating object may be a wiring board having metal interconnections, formed of copper or the like.

As described above, the plating solution for forming a tin alloy, according to the previous embodiment of the present invention, is high in stability and plating rate, and enables temperature control for the control of the plating rate.

Furthermore, according to the exemplary embodiment of the present invention, electrons required for the precipitation of tin, indium and zinc are supplied by the oxidation of the reducing agent. Since no metal in the plating object is dissolved, damage to the plating object, such as corrosion or the like, does not occur, and a dense tin film with a uniform thickness can be formed. Accordingly, a mounting board can be manufactured without loss in, for example, metal patterns configured into a thin film type.

According to an exemplary embodiment of the present invention, bonding pads for bonding with stud bump on a printed circuit board may be formed by the method of forming a tin alloy film.

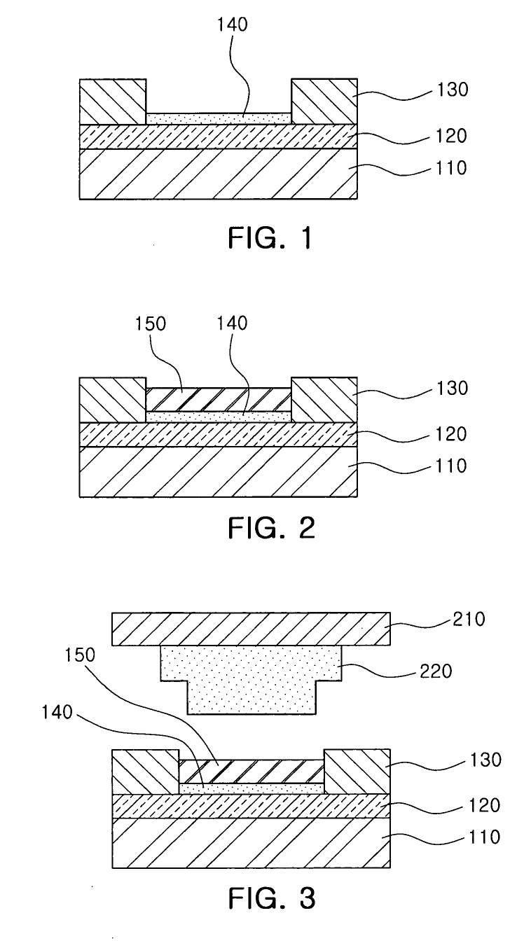

FIGS. 1 through 3 are schematic cross-sectional views illustrating a method of forming a tin alloy film on a printed circuit board, according to an exemplary embodiment of the present invention.

First, as shown in FIG. 1, a printed circuit board for the mounting a semiconductor chip or the like is prepared.

The printed circuit board includes a circuit pattern 120 on an insulating layer 110. A solder resist layer 130 is formed on a portion of the circuit pattern 120 other than a region thereof on which a bonding pad is to be formed.

The circuit pattern 120 may be formed of conductive metal generally used as a circuit layer in the field of printed circuit boards. For example, copper may be used for the circuit pattern 120.

Thereafter, a nickel layer 140 is formed on the region on which a bonding pad is to be formed and which is exposed through the solder resist layer 130. The nickel layer 140 may be formed by electro-plating, electroless reduction or immersion plating, or the like. The nickel layer 140 may have a thickness of 0.8 μm or greater.

Thereafter, as shown in FIG. 2, a tin alloy film 150 is formed on the nickel layer 140.

As described above, the tin alloy film 150 may be formed by immersing the printed circuit board in the plating solution for forming a tin alloy film according to the previous embodiment of the present invention. The tin alloy film 150 may be In—Sn, Zn—Sn or In—Zn—Sn.

Subsequently, as shown in FIG. 3, a stud bump 220 formed on a semiconductor chip 210 is mounted on the tin alloy film 150.

According to this exemplary embodiment of the present invention, the nickel layer 140 is formed between the circuit pattern 120 and the tin alloy film 150, thereby suppressing the generation of an intermetallic compound (IMC) between copper and the tin alloy film 150, and suppressing the generation of whiskers.

Accordingly, defective bonding between the printed circuit board and the semiconductor chip, and deterioration in reliability can be prevented from occurring.

Hereinafter, the present invention will be described in more detail with reference to inventive examples.

Plating solutions for electrolessly forming a tin alloy, having compositions as described in Table 1 below, were prepared, and electroless tin alloy plating was performed upon a copper layer.

TABLE 1

| | Inventive example 1 | Inventive example 2 |
|---|---|---|
| Tin salt | Tin oxalate 10 g/L | Tin oxalate 10 g/L |
| (content) | | |
| Metal salt | Indium acetate 1 g/L | Zinc acetate 1 g/L |
| (content) | | |
| First | EDTA 70 g/L | EDTA 70 g/L |
| complexing | | |
| agent | | |
| (content) | | |
| Second | Oxalate 5 g/L | Citrate 18 g/L |
| complexing | | |
| agent | | |
| (content) | | |
| Reducing agent | NaBH₄ 3 g/L | NaBH₄ 3 g/L |
| (content) | | |
| Accelerator | Sodium acetate 4.0 g/L | Sodium acetate 4.0 g/L |
| pH | 10.3 | 10.3 |
| Temperature | 45□ | 45□ |

The surfaces of the tin alloy films, according to inventive examples 1 and 2 were observed by using Scanning Electron Microscopy (SEM) (a Nova Namo SEM 200 from FEI), and it was confirmed that they were tin alloy surfaces through qualitative and quantitative analysis (the use of a Genesis 2000 EDS from EDAX).

Furthermore, in order to prove that the tin alloy plating was conducted by reduction plating, not by immersion plating, a Cu concentration within a solution after plating was analyzed. The analysis revealed that a Cu concentration was 1 mg/L or less and thus Cu barely existed therein. In this manner, the plating method was determined to be reduction plating, rather than immersion plating.

While the present invention has been shown and described in connection with the exemplary embodiments, it will be apparent to those skilled in the art that modifications and variations can be made without departing from the spirit and scope of the invention as defined by the appended claims.

What is claimed is:

1. A plating solution for forming a tin alloy, the plating solution comprising:
a tin salt and one or more metal salts each comprising indium or zinc; and
at least one reducing agent selected from the group consisting of boron hydride compounds, the reducing agent providing electrons to metal ions of the metal salts and tin ions of the tin salt to thereby form a tin alloy film on an object to be plated.

2. The plating solution of claim 1, wherein the tin salt comprises a ligand having two or more carboxyl groups.

3. The plating solution of claim 1, wherein the tin salt comprises an oxalate expressed by a chemical formula below:

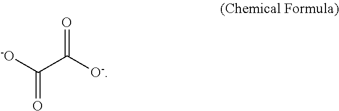

4. The plating solution of claim 1, wherein a content of the tin salt ranges from 5 g/L to 20 g/L.

5. The plating solution of claim 1, wherein a content of the one or more metal salts comprising the indium or the zinc ranges from 1 g/L to 10 g/L.

6. The plating solution of claim 1, wherein the boron hydride compound is sodium boron hydride, potassium boron hydride, or lithium boron hydride.

7. The plating solution of claim 1, wherein a content of the reducing agent ranges from 1 g/L to 10 g/L.

8. The plating solution of claim 1, wherein the plating solution for forming a tin alloy has a pH of between 10 and 11.

9. The plating solution of claim 1, further comprising at least one additive selected from the group consisting of a complexing agent, an accelerator and an oxidation inhibitor.

10. The plating solution of claim 1, further comprising:
at least one first complexing agent selected from the group consisting of a carbonyl compound or an amino compound having a shared electron pair to allow for a coordinate bond with the metal ions and the tin ions; and
at least one second complexing agent selected from the group consisting of a carbonyl compound and an amino compound having lower bonding energy with respect to the tin ions than that of the first complexing agent.

11. The plating solution of claim 10, wherein a content of the first complexing agent ranges from 50 g/L to 150 g/L, and a content of the second complexing agent ranges from 1 g/L to 20 g/L.

12. A method of forming a tin alloy film, the method comprising:
preparing a plating solution for forming a tin alloy, the plating solution comprising: a tin salt and one or more metal salts each comprising indium or zinc; and at least one reducing agent selected from the group consisting of boron hydride compounds, the reducing agent providing electrons to metal ions of the metal salts and tin ions of the tin salt for formation of a tin alloy film on an object to be plated; and
immersing the object into the plating solution to thereby form a tin alloy film.

13. The method of claim 12, wherein the tin salt is tin oxalate including an oxalate expressed by a chemical formula below:

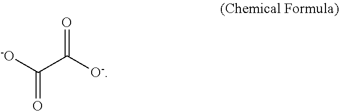

14. The method of claim 12, wherein the plating solution has a pH of between 10 and 11.

15. The method of claim 12, wherein the object to be plated is a printed circuit board, and the tin alloy film is formed on a circuit pattern of the printed circuit board to thereby form a pad for bonding with a stub bump.

16. The method of claim 15, further comprising forming a nickel layer on the circuit pattern before the forming of the tin alloy film.
